(19) United States
(12) Patent Application Publication
(10) Pub. No.: US 2023/0170322 A1
(43) Pub. Date: Jun. 1, 2023

(54) GANG CLIP WITH MOUNT COMPOUND ARRESTER

(71) Applicant: Texas Instruments Incorporated, Dallas, TX (US)

(72) Inventors: Ernesto Pentecostes Rafael, JR., Magalang (PH); Kristina Dianne Hernandez Sazon, Capas (PH); Dior Yñigo Medina Gadia, Porac (PH)

(21) Appl. No.: 17/536,498

(22) Filed: Nov. 29, 2021

(51) Int. Cl. H01L 23/00; H01L 25/065; H01L 23/495

(52) U.S. Cl. CPC H01L 24/37; H01L 24/32; H01L 24/38; H01L 25/0657; H01L 23/49575; H01L 2224/32245; H01L 2224/3702; H01L 2924/38

(57) ABSTRACT

An integrated circuit package includes a lead frame, a first die adhered to the lead frame on a first side of the first die, and a first clip having a clip foot adhered to the lead frame. The first clip has a first side and a second side. A first die attachment region is defined by a first group of four notches in the first side of the first clip. The first clip extends from the lead frame and contacts a second side of the first die at the first die attachment region via a first layer of solder paste. The integrated circuit package further has a second die adhered to the second side of the first clip on a first side of the second die, and a second clip having a clip foot adhered to the lead frame. The second clip has a first side and a second side. A second die attachment region is defined by a second group of four notches in the first side of the second clip. The second clip extends from the lead frame and contacts a second side of the second die at the second die attachment region via a second layer of solder paste.

### BACKGROUND

Integrated circuit (IC) packages typically include at least one die and at least one substrate to which the die is attached by an attachment medium such as solder or epoxy. The substrate facilitates electrical attachment of the die to other electronics, which may be within or outside the IC package. The various components of the IC package are generally encased in a protective mold compound, such as epoxy. A quad flat no lead (QFN) package is one type of IC package used to package vertically stacked dies. In a QFN package, dies, lead frames and electrical connection clips are arranged in a vertical stack and are interconnected by an attachment medium such as solder or epoxy. In contrast to the techniques of attaching a die by adhesive bonding or wire soldering, high-power packages and discrete devices, such as metal oxide semiconductor field effect transistors (MOSFETs), insulated gate bipolar transistors (IGBTs), and switched output differential structures (SODs) use solder paste to connect the die to the basic substrate and/or leads. Clip-bonding technology partially replaces the standard wire-bond connection between a die and a lead by a clip (e.g., a copper clip), which is also soldered by solder paste. Clip bonding allows for unique package resistance, better thermal transfer, and ultra-fast switching performance due to the small package.

### SUMMARY

In one example, an integrated circuit package includes a lead frame, a first die adhered to the lead frame on a first side of the first die, and a first clip having a clip foot adhered to the lead frame. The first clip has a first side and a second side. A first die attachment region is defined by a first group of four notches in the first side of the first clip. The first clip extends from the lead frame and contacts a second side of the first die at the first die attachment region via a first layer of solder paste. The integrated circuit package further has a second die adhered to the second side of the first clip on a first side of the second die, and a second clip having a clip foot adhered to the lead frame. The second clip has a first side and a second side. A second die attachment region is defined by a second group of four notches in the first side of the second clip. The second clip extends from the lead frame and contacts a second side of the second die at the second die attachment region via a second layer of solder paste.

In another example, an integrated circuit package includes a lead frame, a first die attached to the lead frame, a first clip attached to the first die and the lead frame, a second die attached to first clip, and a second clip attached to the second die and the lead frame. The first clip has a first side and a second side. A first group of four trenches are etched on the first side of the first clip. The first clip extends from the lead frame and contacts the first die at a first die attachment region via a first layer of solder paste. The first die attachment region comprises a rectangular area defined by the first group of four trenches. The second clip has a first side and a second side. A second group of four trenches are etched on the first side of the second clip. The second clip extends from the lead frame and contacts the second die at a second die attachment region via a second layer of solder paste. The second die attachment region comprises a rectangular area defined by the second group of four trenches. A mold compound encapsules at least a portion of the lead frame, the first die, the first clip, the second die, and the second clip.

A method of manufacturing an integrated circuit package includes forming a first layer of solder paste on a lead frame, adhering a first die to the lead frame on a first side of the first die via the first layer of solder paste, and forming a second layer of solder paste on a second side of the first die. The second side of the first die opposing the first side of the first die. The method further includes adhering a clip foot of a first clip to the lead frame and adhering a first side of the first clip to the second side of the first die via the second layer of solder paste. The first side of the first clip has four trenches defining a first die attachment area. The method further includes forming a third layer of solder paste on a second side of the first clip, wherein the second side of the first clip opposes the first side of the first clip, adhering a second die to the second side of the first clip on a first side of the second die via the third layer of solder paste, forming a fourth layer of solder paste on a second side of the second die, adhering a clip foot of a second clip to the lead frame and adhering the second clip to the second side of the second die via the fourth layer of solder paste. The first side of the second clip has four trenches defining a second die attachment area. The method further includes reflowing the first layer, the second layer, the third layer and the fourth layer of solder paste, wherein the four trenches defining first die attachment area are configured to prevent the second layer of solder paste from expanding beyond the first die attachment area, and wherein the four trenches defining the second die attachment area are configured to prevent the fourth layer of solder paste from expanding beyond the second die attachment area.

### BRIEF DESCRIPTION OF THE DRAWINGS

Having thus described the invention in general terms, reference will now be made to the accompanying drawings, wherein:

FIG. 1 is a top view of an integrated circuit package that employs clip bonding techniques to bond semiconductor dies of the IC package to a lead frame.

FIG. 2 is a side view of the IC package shown in FIG. 1 illustrating the layers therein.

FIG. 3 is a widthwise cross section view of the IC package shown in FIG. 1 illustrating the layers therein.

FIG. 4 is a cross section view of the IC package shown in FIG. 2 illustrating a bottom surface of a cantilever beam portion of a first clip.

FIG. 5 is a cross section view of the IC package shown in FIG. 2 illustrating a bottom surface of a cantilever beam portion of a second clip.

FIGS. 6A-D illustrate the application of solder paste to a semiconductor die and the subsequent spread of the solder paste when a clip is attached to the semiconductor die according to one example.

FIG. 7 is a flow diagram for a method for packaging an electronic device in accordance with various examples.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In the drawings, like reference numerals refer to like elements throughout, and the various features are not necessarily drawn to scale. Corresponding numerals and symbols in the different figures generally refer to corresponding parts, unless otherwise indicated. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

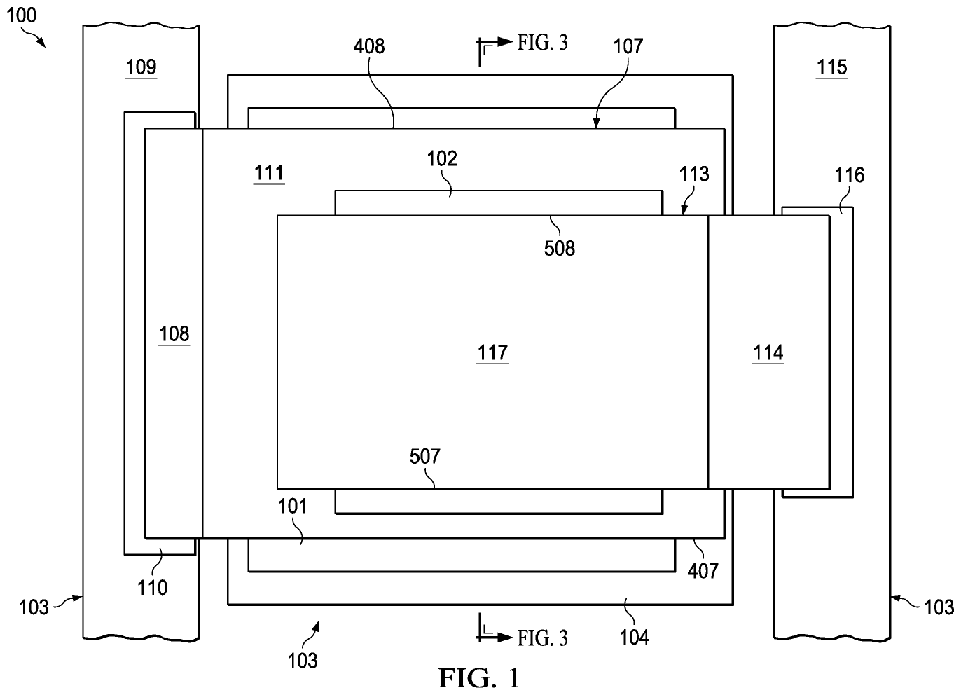

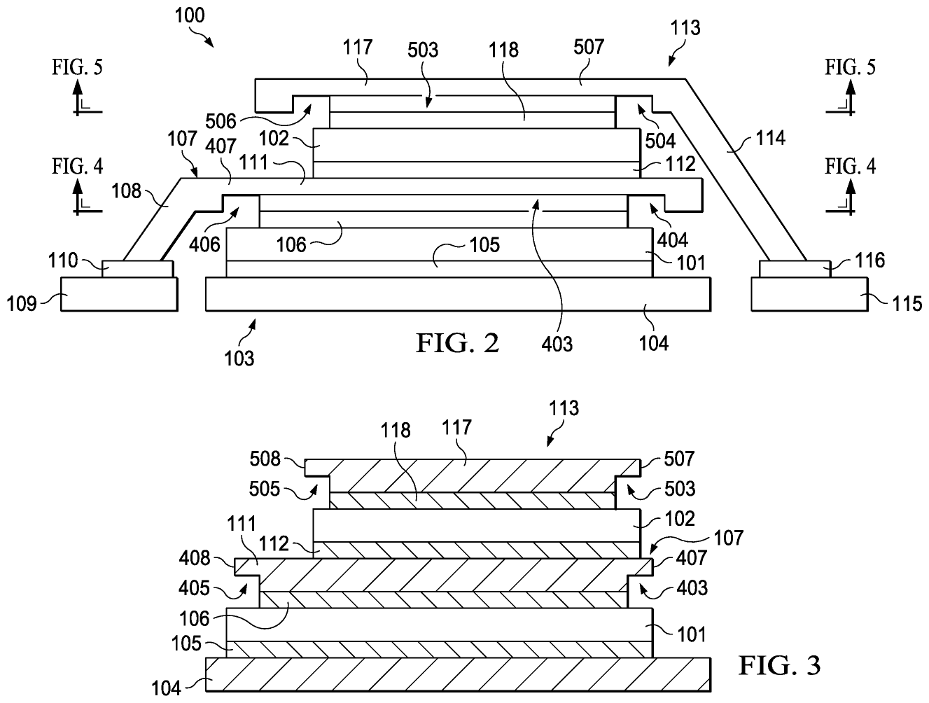

FIG. 1 is a top view of an integrated circuit (IC) package 100 that employs clip bonding techniques to bond semiconductor dies 101, 102 of the IC package 100 to a lead frame 103. FIG. 2 is a side view of IC package 100 illustrating the layers therein. FIG. 3 is a cross section view of IC package 100. As used herein, the term “lead frame” refers to a structure in an IC package that carries signals between dies of the IC package and external components. The structure may be singulated from a lead frame strip having multiple segments for multiple IC packages. In one example, the lead frame 103 is a lead frame for a quad-flat no leads (QFN) IC package. In other examples, the lead frame 103 is employable in other types of IC packages. The IC package 100 is implemented as a multi-die IC package. In the examples illustrated, there are two dies, but in other examples, there could be more than two dies. The semiconductor dies 101, 102 may be metal oxide semiconductor field effect transistors (MOSFET), bipolar transistors, integrated circuits, or other semiconductor devices. The semiconductor dies 101, 102 may be the same or different types of devices.

A first die 101 overlies a first portion 104 of the lead frame 103. A bottom surface of the first die 101 is adhered to, and coupled to, the first portion 104 of lead frame 103 via a first layer of solder paste 105. A second layer of solder paste 106 overlays the first die 101. To simplify the explanation herein, the terms top and bottom are employed throughout this disclosure to denote opposing surfaces. Similarly, the terms overlay, underlie, vertical and horizontal (and their derivatives) are employed to denote relative positions in a described arrangement. Moreover, the examples used throughout this disclosure denote one possible orientation. However, other orientations are possible, such as upside down, rotated by 90 degrees, etc.

A first clip 107 includes a clip foot 108 adhered to a second portion 109 of the lead frame 103 via solder paste 110. As used herein, the term “clip” refers to a rigid bridge employed to implement clip bonding between a lead frame (e.g., the second portion 109 of the lead frame 103) and one or more dies (e.g., the first die 101) of an IC package (e.g., the IC package 100). Additionally, as used herein, the term “clip foot” refers to a region of a clip that is adhered to a lead frame. In some examples, the solder paste 110 is formed with the first layer of solder paste 106 in a prior etching process. The first clip 107 extends from the clip foot 108 to a cantilever beam portion 111 that overlays the first die 101. The first clip 107 is adhered and electrically coupled to the first die 101 via the second layer of solder paste 106. The first clip 107 may be formed of copper or other conductive material.

A third layer of solder paste 112 overlays the cantilever beam portion 111 of first clip 107. Additionally, a second die 102 overlays the first clip 107. More particularly, the second die 102 is adhered and, in some examples, electrically coupled to the first clip 107 via the third layer of solder paste 112. In some examples, the second die 102 has a smaller footprint than the first die 101.

A second clip 113, such as a gang clip, includes a first clip foot 114 adhered to a third portion 115 of the lead frame 103 via solder paste 116. In some examples, the second clip 113 is a solid bridge (e.g., a clip formed of copper or other conductive material). Additionally, in some examples, the second clip 113 represents a singulated portion of a larger second clip that (prior to singulation) contacted multiple dies in an array of IC structures. One end of the first clip foot 114 is adhered to the third portion 115 of the lead frame 103 via solder paste 116. The solder paste 116 may be a portion of the first layer of solder paste 106 that has been etched away. The second clip 113 extends from the second clip foot 114 to a cantilever beam portion 117 that overlays the second die 102. The second clip 113 is adhered and electrically coupled to the second die 102 via a fourth layer of solder paste 118.

In some examples, solder paste 105, 106, 112, 118 may be referred to as mount compound. The layers of solder paste 105, 106, 112, 118 may be formed using additive process as a material extrusion that dispenses solder paste onto the lead frame 104, first die 101, first clip 107, or second die 102, respectively. The solder paste may include tin and may include flux, solvents, surfactants, or other materials to facilitate the additive process.

The first clip foot 108 and the second clip foot 114 may extend from lead frame 103 at any angle. In some examples, first clip foot 108 and the second clip foot 114 extend from lead frame 103 at an oblique angle as shown in FIG. 2. In other examples, first clip foot 108 and the second clip foot 114 may extend from lead frame 103 at a 90-degree angle. The first clip foot 108 may be oriented at a different angles than an angle of the second clip foot 114 in other examples.

During manufacture, the amount of solder paste 105, 106, 112, 118 applied may vary depending upon process parameter margins, such as dispense pressure and dispense height. Excessive amounts of solder paste may be dispensed in some cases, which can cause the solder to bridge clips 111, 117 and the grounding for IC dies 101, 102 thereby causing electrical shorts. In one example, a notch is created around the periphery of a contact region on the clips 111, 117 to eliminate the risk of the solder paste 106 and 118 bridging the clips 111, 117. The notch may be created as a half-etch on the underside of the clip. In some examples, the notch may be referred to as a trench, channel, slot, or aperture.

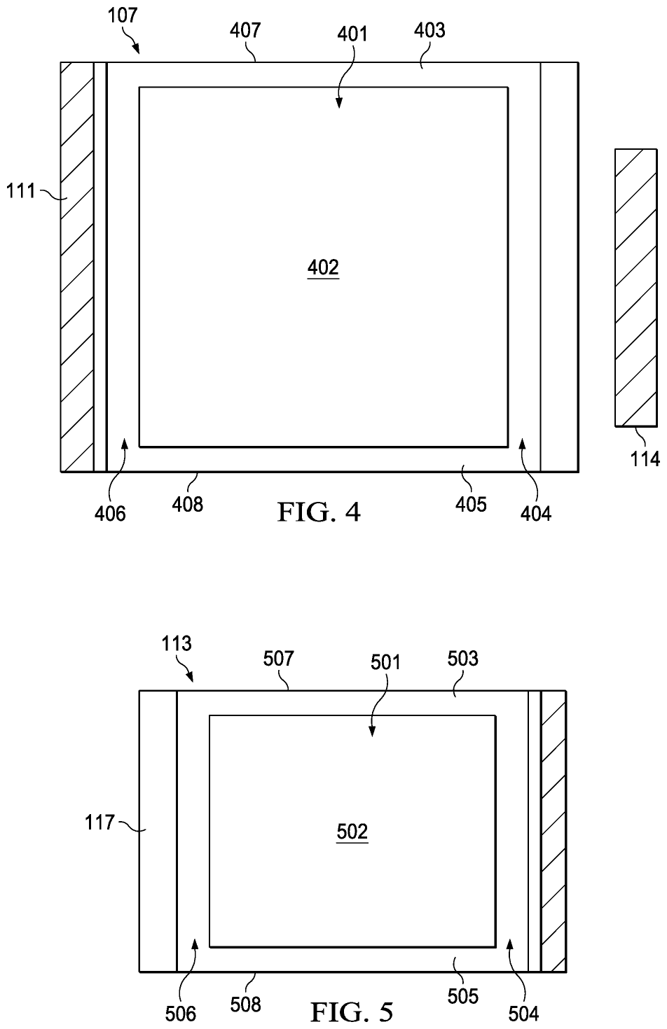

FIG. 4 is a cross section view of IC package 100 as indicated in FIG. 2 showing a bottom surface 401 of the cantilever beam 111 portion of first clip 107. Bottom surface 401 includes an IC die attachment region 402 that is configured to receive the layer of solder paste 106 for attachment to first semiconductor die 101. Die attachment region 402 is surrounded by four notches 403-406, which are also indicated in FIGS. 2 and 3. Notches 404 and 406 extend from a first edge 407 to a second edge 408 of cantilever beam 111. Notch 403 extends along edge 407 from notch 404 to notch 406. Notch 405 extends along edge 408 from notch 404 to notch 406.

In one example, the notches 403-406 are half etched from the bottom surface 401 of first clip 107. For example, if the thickness of cantilever beam 111 is 254 micrometers (μm), notches 403-406 may be created by etching 127 μm of material from the bottom surface 401. In other examples, the depth of notches 403-406 from bottom surface 401 may vary and may be more or less than a half-etch depth. The width of notches 403-406 may vary and in some examples have a maximum width of 80 μm.

Notches 403-406 are configured to catch excessive solder paste 106 to prevent the solder from creeping to the active circuit of the first die 101 when the first clip 107 is attached. For example, a solder paste for layer 106 may be dispensed on the top of first die 101, and then first clip 107 is attached on top of the first die 101. When the first clip 107 is attached, the solder paste spreads across the top of first die 101 and across region 402 until reaching the half-etched areas forming notches 403-406. These notches 403-406 arrest the excessive solder paste and prevent solder layer 106 from bridging the first die 101 to other components and causing an electrical short.

FIG. 5 is a cross section view of IC package 100 as indicated in FIG. 2 showing a bottom surface 501 of the cantilever beam 117 portion of second clip 113. Bottom surface 501 includes an IC die attachment region 502 that is configured to receive the layer of solder paste 118 for attachment to second semiconductor die 102. Die attachment region 502 is surrounded by four notches 503-506, which are also indicated in FIGS. 2 and 3. Notches 504 and 506 extend from a first edge 507 to a second edge 508 of cantilever beam 117. Notch 503 extends along edge 507 from notch 504 to notch 506. Notch 505 extends along edge 508 from notch 504 to notch 506.

In one example, the notches 503-506 are half etched from the bottom surface 501 of second clip 113. For example, if the thickness of cantilever beam 117 is 254 μm, notches 503-506 may be created by etching 127 μm of material from the bottom surface 501. In other examples, the depth of notches 503-506 from bottom surface 501 may vary and may be more or less than a half-etch depth. The width of notches 503-506 may vary and in some examples have a maximum width of 80 μm.

Notches 503-506 are configured to catch excessive solder paste 118 to prevent the solder from creeping to the active circuit of the second die 102 when the second clip 113 is attached. For example, a solder paste for layer 118 may be dispensed on the top of second die 102, and then second clip 113 is attached on top of the second die 102. When the second clip 113 is attached, the solder paste spreads across the top of second die 102 and across region 502 until reaching the half-etched areas forming notches 503-506. These notches 503-506 arrest the excessive solder paste and prevent solder layer 118 from bridging the second die 102 to other components and causing an electrical short.

Notches or half-etched areas 403-406 and 503-506 may be implemented using standard etching techniques for clip fabrication. The notches 403-406 and 503-506 may be observed, for example, through x-ray inspection of either a top or side view. The half etch area will appear as having more or additional solder coverage across all sides of the clips 107, 113 to semiconductor die 101, 102 interface. The notch areas 403-406 and 503-506 provide a solder escape path and thereby reduce the risk of shorting the two interfaces.

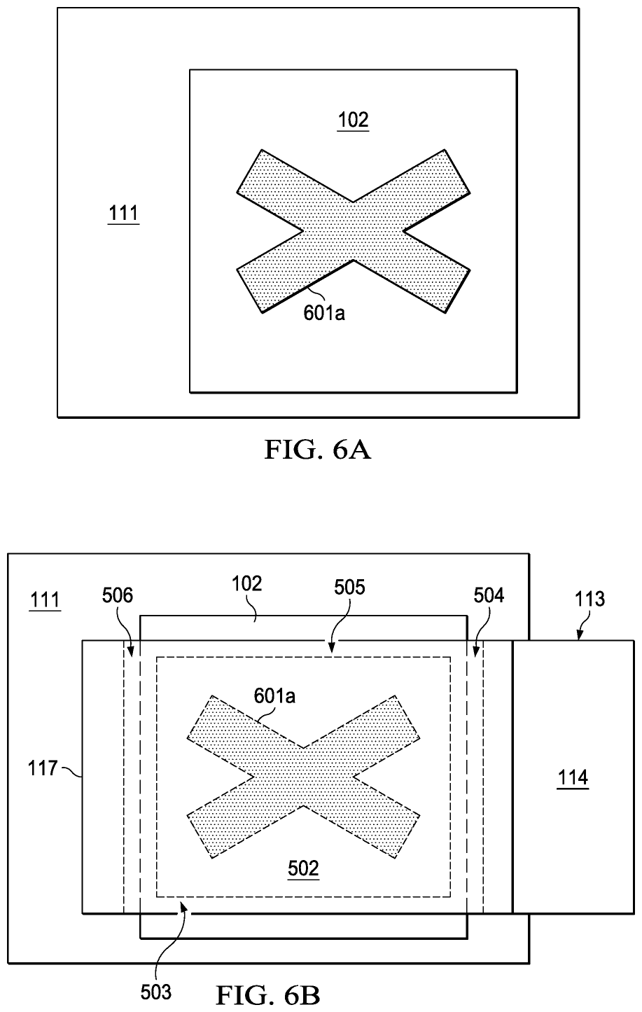

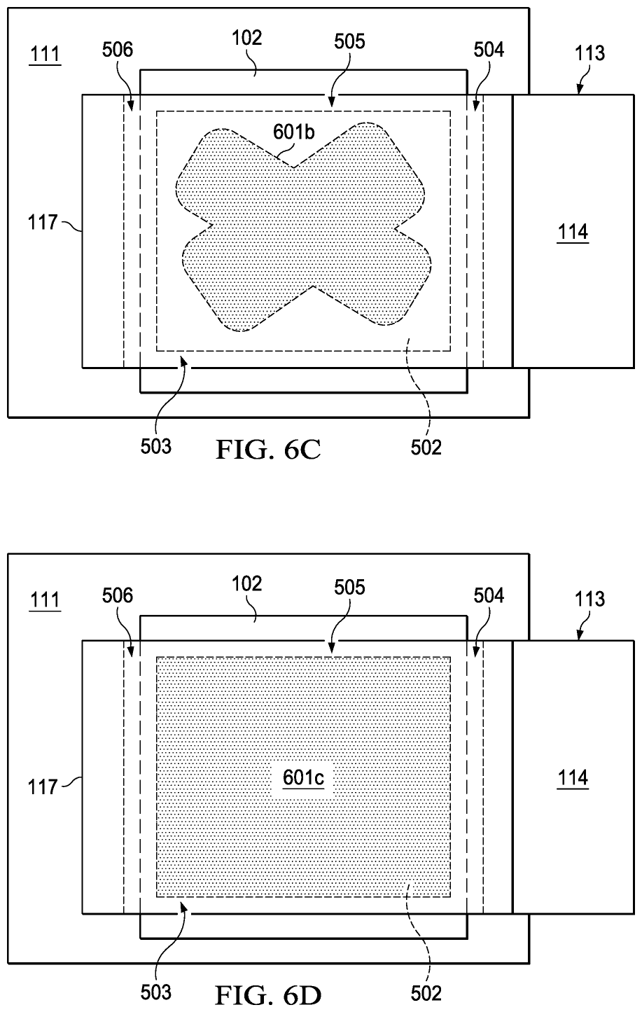

FIGS. 6A-D illustrate the application of solder paste to a semiconductor die and the subsequent spread of the solder paste when a clip is attached to the semiconductor die according to one example. FIG. 6A shows some components of the IC package 100 described in FIGS. 1-5. A cantilever beam 111 portion of a first clip overlays a first die 101 (not shown). The second die 102 is adhered and, in some examples, electrically coupled to the cantilever beam 111 portion of the first clip via a layer of solder paste 112 (not shown). Solder paste 601a is then applied on top of semiconductor die 102. In one example, the solder paste 601a may be applied using solder paste dispensing methods, such as a screen-printing method.

FIG. 6B shows a second clip 113 positioned above the semiconductor die 102 before attachment to semiconductor die 102. The second clip 113 has a clip foot 114 portion and a cantilever beam portion 117. As described herein, the bottom surface of cantilever beam 117 has been etched to create a die attachment region 502 that is surrounded by four notches or channels 503-506.

FIG. 6C shows the second clip 113 being attached to semiconductor die 102, such as by pressing the die attachment region 502 on the bottom surface of cantilever beam portion 117 against the top of the semiconductor die 102. As die attachment region 502 moves toward the top of semiconductor die 102, the solder paste 601b begins to spread out in all directions across the top of semiconductor die 102.

FIG. 6D shows the solder paste 601c spreading across the top of semiconductor die 102 and underneath of cantilever beam portion 117 until reaching the etched channels 503-506, which arrest the flow of excessive solder paste 601c to prevent the solder paste 601c from bridging semiconductor die 102 and the second clip 113. In one example, the solder paste 601c forms the layer of solder paste 118 between semiconductor die 102 and clip 113 that adheres and electrically couples the second die 102 and the second clip 113.

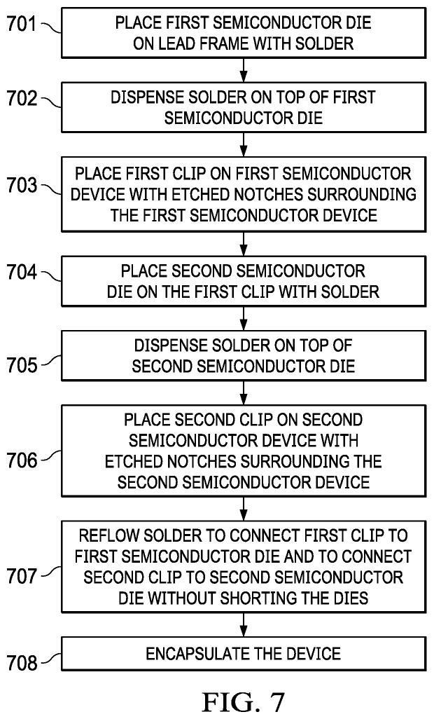

FIG. 7 is a flow diagram for a method 700 for packaging an electronic device in accordance with various examples. Though depicted sequentially as a matter of convenience, at least some of the actions shown can be performed in a different order and/or performed in parallel. Additionally, some implementations of the method 700 may perform only some of the actions shown.

In block 701, the first semiconductor dies 101 is placed on the lead frame 103. Solder 105 is applied to the lead frame 103 before the first semiconductor die 101 is placed on the lead frame 103. In block 702, solder 106 is dispensed to the top of semiconductor die 101. In block 703, the first clip 107 is disposed on the first semiconductor die 101. Solder 106 is applied to the first semiconductor die 101 before the first clip 107 is placed on the first semiconductor die 101. Disposing the first clip 107 on the first semiconductor die 101 includes aligning the first clip 107 with the first semiconductor die 101 so that the half-etched notches 403-406 surround the periphery of the first semiconductor die 101. The first clip 107 is positioned to conductively connect terminals on the first semiconductor die 101 to terminals on the lead frame 103.

In block 704, the second semiconductor die 102 is disposed on the first clip 107. Solder 112 is applied to the first clip 107 before the second semiconductor die 102 is placed on the first clip 107. In block 705, solder is dispensed to the top of the second semiconductor die 102. In block 706, the second clip 113 is disposed on the second semiconductor die 102. Solder 118 is applied to the second semiconductor die 102 before the second clip 113 is placed on the second semiconductor die 102. Disposing the second clip 113 on the second semiconductor die 102 includes aligning the second clip 113 with the second semiconductor die 102 so that the half-etched notches 503-506 surround the periphery of the second semiconductor die 102. The second clip 113 is positioned to conductively connect terminals on the second semiconductor die 102 to terminals on the lead frame 103.

In block 707, the solder 106 and 118 is heated and reflows to connect the first clip 107 to the first semiconductor die 101 and to connect the second clip 113 to the second semiconductor die 102. The notches 403-406, 503-506 in clips 107, 113 prevent solder 106 and 118 from overflowing the bottom surface of the clips 107, 113 and shorting the semiconductor dies 101, 102. In block 708, the device formed by the component stack, or a portion thereof, in blocks 701-707 is encapsulated with a mold compound (e.g., encased in plastic). In some examples, multiple devices are formed on the lead frame, and the devices are singulated after encapsulation.

An example integrated circuit package includes a lead frame, a first die adhered to the lead frame on a first side of the first die, and a first clip having a clip foot adhered to the lead frame. The first clip has a first side and a second side. A first die attachment region is defined by a first group of four notches in the first side of the first clip. The first clip extends from the lead frame and contacts a second side of the first die at the first die attachment region via a first layer of solder paste. The example integrated circuit package further includes a second die adhered to the second side of the first clip on a first side of the second die, and a second clip having a clip foot adhered to the lead frame. The second clip has a first side and a second side. A second die attachment region is defined by a second group of four notches in the first side of the second clip. The second clip extends from the lead frame and contacts a second side of the second die at the second die attachment region via a second layer of solder paste. The first group of four notches is configured to prevent the first layer of solder paste from expanding beyond the first die attachment region. The second group of four notches is configured to prevent the second layer of solder paste from expanding beyond the second die attachment region. A portion of the second clip may extend over the first clip.

The first group of four notches may be etched, such as half-etched, into the first side of the first clip, and the second group of four notches may be etched, such as half-etched, into the first side of the second clip.

The first group of four notches may comprise a first notch and a second notch, wherein both the first notch and the second notch extend from a first edge of the first clip to a second edge of the first clip. The first group of four notches may further comprise a third notch extending along the first edge and a fourth notch extending along the second edge.

The second group of four notches may comprise a first notch and a second notch, wherein both the first notch and the second notch extend from a first edge of the second clip to a second edge of the second clip. The second group of four notches may further comprise a third notch extending along the first edge and a fourth notch extending along the second edge.

The example integrated circuit package may further include a third layer of solder paste adhering the first die to the lead frame, and a fourth layer of solder paste adhering the second die to the second side of the first clip.

The example integrated circuit package may further include a mold compound encapsulating at least a portion of the lead frame, the first die, the first clip, the second die, and the second clip.

Another example integrated circuit package includes a lead frame, a first die attached to the lead frame, a first clip attached to the first die and the lead frame, a second die attached to first clip, and a second clip attached to the second die and the lead frame. The first clip has a first side and a second side. A first group of four trenches are etched on the first side of the first clip. The first clip extends from the lead frame and contacts the first die at a first die attachment region via a first layer of solder paste. The first die attachment region comprises a rectangular area defined by the first group of four trenches. The second clip has a first side and a second side. A second group of four trenches are etched on the first side of the second clip. The second clip extends from the lead frame and contacts the second die at a second die attachment region via a second layer of solder paste. The second die attachment region comprises a rectangular area defined by the second group of four trenches. The first group of four trenches may be half-etched into the first side of the first clip, and the second group of four trenches may be half-etched into the first side of the second clip. The first group of four trenches is configured to prevent the first layer of solder paste from expanding beyond the first die attachment region, and the second group of four trenches is configured to prevent the second layer of solder paste from expanding beyond the second die attachment region. A portion of the second clip may extend over the first clip. A mold compound encapsulates at least a portion of the lead frame, the first die, the first clip, the second die, and the second clip.

The first group of four trenches comprises a first trench and a second trench that each extend from a first edge of the first clip to a second edge of the first clip. The first group of four trenches further comprises a third trench extending along the first edge and a fourth trench extending along the second edge.

The second group of four trenches comprises a first trench and a second trench that each extend from a first edge of the second clip to a second edge of the second clip. The second group of four trenches further comprises a third trench extending along the first edge and a fourth trench extending along the second edge.

The example integrated circuit package may further include a third layer of solder paste adhering the first die to the lead frame, and a fourth layer of solder paste adhering the second die to the second side of the first clip.

An example method for forming an integrated circuit package includes the steps of forming a first layer of solder paste on a lead frame, adhering a first die to the lead frame on a first side of the first die via the first layer of solder paste, and forming a second layer of solder paste on a second side of the first die, wherein the second side of the first die opposing the first side of the first die. The example method for forming an integrated circuit package further includes the steps of adhering a clip foot of a first clip to the lead frame and adhering a first side of the first clip to the second side of the first die via the second layer of solder paste, wherein the first side of the first clip having four trenches defining a first die attachment area. The example method for forming an integrated circuit package further includes forming a third layer of solder paste on a second side of the first clip, wherein the second side of the first clip opposes the first side of the first clip, adhering a second die to the second side of the first clip on a first side of the second die via the third layer of solder paste, forming a fourth layer of solder paste on a second side of the second die, adhering a clip foot of a second clip to the lead frame, and adhering the second clip to the second side of the second die via the fourth layer of solder paste, wherein the first side of the second clip having four trenches defining a second die attachment area. The example method for forming an integrated circuit package further includes reflowing the first layer, the second layer, the third layer and the fourth layer of solder paste, wherein the four trenches defining first die attachment area are configured to prevent the second layer of solder paste from expanding beyond the first die attachment area, and wherein the four trenches defining the second die attachment area are configured to prevent the fourth layer of solder paste from expanding beyond the second die attachment area. The example method for forming an integrated circuit package further includes encapsulating at least a portion of the lead frame, the first die, the first clip, the second die, and the second clip with a mold compound.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. An integrated circuit (IC) package, comprising:
a lead frame;
a first die adhered to the lead frame on a first side of the first die;
a first clip having a clip foot adhered to the lead frame, the first clip having a first side and a second side, a first die attachment region defined by a first group of four notches in the first side of the first clip, the first clip extending from the lead frame and contacting a second side of the first die at the first die attachment region via a first layer of solder paste;
a second die adhered to the second side of the first clip on a first side of the second die; and
a second clip having a clip foot adhered to the lead frame, the second clip having a first side and a second side, a second die attachment region defined by a second group of four notches in the first side of the second clip, the second clip extending from the lead frame and contacting a second side of the second die at the second die attachment region via a second layer of solder paste.

2. The IC package of claim 1, wherein the first group of four notches are etched into the first side of the first clip, and the second group of four notches are etched into the first side of the second clip.

3. The IC package of claim 1, wherein the first group of four notches are half-etched into the first side of the first clip, and the second group of four notches are half-etched into the first side of the second clip.

4. The IC package of claim 1, wherein the first group of four notches is configured to prevent the first layer of solder paste from expanding beyond the first die attachment region.

5. The IC package of claim 1, wherein the first group of four notches comprises a first notch and a second notch extending from a first edge of the first clip to a second edge of the first clip, a third notch extending along the first edge, and a fourth notch extending along the second edge.

6. The IC package of claim 1, wherein the second group of four notches is configured to prevent the second layer of solder paste from expanding beyond the second die attachment region.

7. The IC package of claim 1, wherein the second group of four notches comprises a first notch and a second notch extending from a first edge of the second clip to a second edge of the second clip, a third notch extending along the first edge, and a fourth notch extending along the second edge.

8. The IC package of claim 1, further comprising:
a third layer of solder paste adhering the first die to the lead frame; and
a fourth layer of solder paste adhering the second die to the second side of the first clip.

9. The IC package of claim 1, further comprising:
a mold compound encapsulating at least a portion of the lead frame, the first die, the first clip, the second die, and the second clip.

10. The IC package of claim 1, wherein a portion of the second clip extends over the first clip.

11. An integrated circuit (IC) package, comprising:
a lead frame;
a first die attached to the lead frame;
a first clip attached to the first die and the lead frame;
a second die attached to first clip;
a second clip attached to the second die and the lead frame;
the first clip having a first side and a second side, a first group of four trenches are etched on the first side of the first clip, the first clip extending from the lead frame and contacting the first die at a first die attachment region via a first layer of solder paste, the first die attachment region comprising a rectangular area defined by the first group of four trenches; and
the second clip having a first side and a second side, a second group of four trenches are etched on the first side of the second clip, the second clip extending from the lead frame and contacting the second die at a second die attachment region via a second layer of solder paste, the second die attachment region comprising a rectangular area defined by the second group of four trenches.

12. The IC package of claim 11, wherein the first group of four trenches are half-etched into the first side of the first clip, and the second group of four trenches are half-etched into the first side of the second clip.

13. The IC package of claim 11, wherein the first group of four trenches is configured to prevent the first layer of solder paste from expanding beyond the first die attachment region, and the second group of four trenches is configured to prevent the second layer of solder paste from expanding beyond the second die attachment region.

14. The IC package of claim 11, wherein the first group of four trenches comprises a first trench and a second trench extending from a first edge of the first clip to a second edge of the first clip, a third trench extending along the first edge, and a fourth trench extending along the second edge.

15. The IC package of claim 11, wherein the second group of four trenches comprises a first trench and a second trench extending from a first edge of the second clip to a second edge of the second clip, a third trench extending along the first edge, and a fourth trench extending along the second edge.

16. The IC package of claim 11, further comprising:
a third layer of solder paste adhering the first die to the lead frame; and
a fourth layer of solder paste adhering the second die to the second side of the first clip.

17. The IC package of claim 11, wherein a portion of the second clip extends over the first clip.

18. The IC package of claim 11, further comprising:
a mold compound encapsulating at least a portion of the lead frame, the first die, the first clip, the second die, and the second clip.

19. A method for forming an integrated circuit (IC) package, the method comprising:
forming a first layer of solder paste on a lead frame;
adhering a first die to the lead frame on a first side of the first die via the first layer of solder paste;
forming a second layer of solder paste on a second side of the first die, the second side of the first die opposing the first side of the first die;
adhering a clip foot of a first clip to the lead frame and adhering a first side of the first clip to the second side of the first die via the second layer of solder paste, the first side of the first clip having four trenches defining a first die attachment area;
forming a third layer of solder paste on a second side of the first clip, wherein the second side of the first clip opposes the first side of the first clip;
adhering a second die to the second side of the first clip on a first side of the second die via the third layer of solder paste;
forming a fourth layer of solder paste on a second side of the second die;
adhering a clip foot of a second clip to the lead frame and adhering the second clip to the second side of the second die via the fourth layer of solder paste, the first side of the second clip having four trenches defining a second die attachment area; and
reflowing the first layer, the second layer, the third layer and the fourth layer of solder paste, wherein the four trenches defining first die attachment area are configured to prevent the second layer of solder paste from expanding beyond the first die attachment area, and wherein the four trenches defining the second die attachment area are configured to prevent the fourth layer of solder paste from expanding beyond the second die attachment area.

20. The method of claim 19, further comprising:
encapsulating at least a portion of the lead frame, the first die, the first clip, the second die, and the second clip with a mold compound.
